(19) United States
(12) Patent Application Publication
(10) Pub. No.: US 2014/0070405 A1
(43) Pub. Date: Mar. 13, 2014

(54) STACKED SEMICONDUCTOR DEVICES WITH A GLASS WINDOW WAFER HAVING AN ENGINEERED COEFFICIENT OF THERMAL EXPANSION AND METHODS OF MAKING SAME

(71) Applicants: Rahul Agarwal, Waterford, NY (US); Ramakanth Alapati, Rexford, NY (US)

(72) Inventors: Rahul Agarwal, Waterford, NY (US); Ramakanth Alapati, Rexford, NY (US)

(73) Assignee: GLOBALFOUNDRIES INC., Grand Cayman (KY)

(21) Appl. No.: 13/613,600

(22) Filed: Sep. 13, 2012

(51) Int. Cl. H01L 23/498; H01L 21/50; H01L 23/48

(52) U.S. Cl. 257/737; 257/774; 438/107; 257/E23.068; 257/E23.011; 257/E21.499

(57) ABSTRACT

One illustrative device disclosed herein includes a device substrate having a plurality of first die formed adjacent a front side of the device substrate, a glass window wafer attached to a back side of the device substrate, wherein the glass window wafer has a plurality of openings formed therein and a coefficient of thermal expansion that is within plus or minus 200-500% of the coefficient of thermal expansion of the device wafer, and a plurality of second die, each of which is positioned in one of the openings in the glass window wafer and electrically coupled to one of the first die.

### BACKGROUND OF THE INVENTION

1. Field of the Invention

Generally, the present disclosure relates to the manufacture of sophisticated semiconductor devices, and, more specifically, to various methods of packaging stacked semiconductor devices using a glass window wafer with an engineered coefficient of thermal expansion (CTE) and packaged semiconductor devices using such a glass window wafer.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Field effect transistors (NFET and PFET transistors) represent one important type of circuit element that substantially determines performance of such integrated circuits. During the fabrication of complex integrated circuits using, for instance, MOS technology, millions of transistors, e.g., NFET transistors and/or PFET transistors, are formed on a substrate including a crystalline semiconductor layer. In recent years, the device features of modern, ultra-high density integrated circuits have been steadily decreasing in size in an effort to enhance the overall speed, performance and functionality of the circuit. As a result, the semiconductor industry has experienced tremendous growth due to the significant and ongoing improvements in integration density of a variety of electronic components, such as transistors, capacitors, diodes and the like. These improvements have primarily come about due to a persistent and successful effort to reduce the critical dimension—i.e., minimum feature size—of components, directly resulting in the ability of process designers to integrate more and more components into a given area of a semiconductor chip. As device features have been aggressively reduced, and more semiconductor components are being fit onto the surface of a single chip, the required number of electrical interconnects necessary for creating the “wiring” for the integrated circuit has dramatically increased. As a result, the overall circuit layout has become more complex and more densely-packed. Furthermore, even though improvements in photolithography processes have yielded significant increases in the integration densities of 2D circuit designs, simple reduction in feature size is rapidly approaching the limits of what can presently be achieved in only two dimensions.

Semiconductor manufacturing typically involves forming a plurality of integrated circuit products or die on the front side of a device wafer. The process operation performed to form the die are so-called front-end-of-line (FEOL) processes (e.g., processes up through and including device formation in the substrate) and back-end-of-line (BEOL) processes (e.g., the formation of various metallization layers that constitute the wiring pattern of the chip). In general, very little of the starting thickness of a device wafer is actually used in making semiconductor devices, i.e., the depth of the device regions in the wafer may be less than 10 μm. Thus, a large percentage of the starting thickness of the device wafer is essentially not needed for the integrated circuit device to perform electrically. Thus, after the FEOL and BEOL processes are completed, the thickness of the device wafer is typically reduced by performing a grinding process on the back side of the device wafer to remove the substrate material until the device wafer is reduced to its final desired thickness. However, the final thickness of the device wafer must be large enough to ensure that the integrated circuit can mechanically withstand packaging operations and withstand the intended commercial environment for the integrated circuit product. In short, there is a constant pressure to reduce the overall thickness of the wafers in the final integrated circuit product. In many applications, e.g., cell phones and other portable consumer electronic devices, it is desirable that the substrate in the integrated circuit product be made as thin as possible to reduce the physical size and weight of the final consumer product.

As the number of electronic devices on single chip rapidly increases, three-dimensional (3D) integrated circuit layouts, or stacked chip design, have been utilized for some semiconductor devices in an effort to overcome some of the feature size and density limitations associated with 2D layouts. Typically, in a 3D integrated circuit design, two or more semiconductor dies are bonded together, and electrical connections are formed between each die. One method of facilitating the chip-to-chip electrical connections is by use of so-called through-substrate vias or through-silicon vias (TSV's). A TSV is a vertical electrical connection that passes completely through a silicon wafer or die, allowing for more simplified interconnection of vertically aligned electronic devices, thereby significantly reducing integrated circuit layout complexity as well as the overall dimensions of a multi-chip circuit. A typical TSV may have a diameter that falls within the range of 6-100 μm or smaller, and, as technology advances, there is constant pressure to make them even smaller.

After an integrated circuit product or chip is manufactured, means must be provided to establish electrical communication with the chip. Typically, this involves formation of conductive “bumps” (in various shapes and forms) that are conductively coupled to the die. In some cases, these conductive bumps can be relatively large, e.g., about 100 μm or so, in diameter. As noted above, after the device wafer containing the plurality of die is manufactured, the device wafer is thinned to its desired final thickness by performing a grinding process on the back side of the device wafer. Before the grinding process begins, the front side of the device wafer is attached to a carrier wafer, typically another silicon wafer, by use of an adhesive material. Unfortunately, due to the physical size of the conductive bumps, the layer of adhesive material between the device wafer and the carrier wafer must be relatively thick, which adds to production costs and time. The presence of the relatively large conductive bumps on the front of the device wafer can also have adverse effects on the thinned wafer that results from the grinding process. More specifically, the relatively high topography associated with the presence of the relatively large conductive bumps on the front side of the device wafer can cause undesirable thickness variations in the thinned wafer.

In an attempt to avoid some of the problems mentioned above with respect to stacked die when the conductive bumps are formed on the front side of the device wafer, various techniques have been employed wherein the conductive bumps are formed on the front side after the stacking had been performed. FIG. 1A depicts one illustrative prior art device 10 at a point during the packaging process after the FEOL and BEOL processing has been performed to form a plurality of integrated circuit products or die 11 (only two of which are depicted) on a front side 12F of a device wafer or substrate 12. The device wafer 12 also has a back side 12B. In this embodiment, a plurality of illustrative TSVs 13 have also been formed in the device wafer 12 and there are no conductive bumps formed on the front side 12F of the device wafer 12. At the point depicted in FIG. 1A, the device wafer 12 has been thinned to its final desired thickness 12T. The device wafer 12 is secured to a carrier wafer or substrate 14 by an adhesive material 16. Also depicted in FIG. 1A is a so-called silicon window wafer 18 and a plurality of stacked die 20 that are electrically coupled to the die 11 on the device wafer 12 by illustrative conductive bumps 22 and the TSVs 13. The stacked die 20 are positioned in openings formed in the silicon window wafer 18. An under-fill material 24 fills the gaps between the stacked die 20, the device wafer 12 and the conductive bumps 22. An adhesive material 25 is used to secure the silicon window wafer 18 to the device wafer 12 and to secure the die 20 in the openings in the window wafer 18. The stacked die 20 and the die 11 depicted in the drawings are intended to be representative of any type or kind of integrated circuit product, e.g., a memory device, a logic device, an ASIC, etc.

The various processes that result in the device 10 depicted in FIG. 1A will now be briefly described. After the FEOL and BEOL processes are completed, the die 11 must be tested, packaged and sold. Typically, the substrate 12 may have a starting thickness, as received from the wafer-supplier, of about 775 μm. Ultimately, depending upon the particular application, prior to performing dicing operations to separate the plurality of die 11, the device substrate 12 will be thinned to a final thickness 12T that may fall within the range of about 20-100 μm. The thinning of the device wafer 12 typically begins by attaching the front side 12F of the wafer 12 to the carrier wafer 14 using the adhesive material 16. Thereafter, a general grinding process is performed on the entirety of the back side 12B of the device substrate 12 to reduce the device substrate 12 to its final desired thickness 12T. Next, the silicon window wafer 18 is attached to the back side 12B of the thinned device wafer 12 by the adhesive material 25. The conductive bumps 22 may be formed on the device wafer 12 prior to the attachment of the silicon window wafer 18, or they may be formed on the stacked die 20. A reflow process is then performed to conductively couple the bumps 22 on conductive bond pads (not shown) on the back side 12B of the substrate 12. The under-fill material 24 is then positioned between the stacked die 20 and the device wafer 12. In some cases, a pre-applied under-fill material may be applied to the stacked die 20 before it is stacked on the die 11. The stacked dies 20 are then secured within the openings in the silicon window wafer 18 by additional adhesive material 25. If desired, additional stacked die may be positioned above the stacked die 20 shown in FIG. 1A. One technique for stacking additional die would be to increase the thickness of the silicon window wafer 18 so as to accommodate the additional die.

FIG. 1B depicts a prior art device 10 that is similar to that shown in FIG. 1A except that the silicon window wafer 18 has been replaced with a molding compound material 28. In this example, the molding material 28 is formed after the stacked dies 20 were conductively coupled to the device wafer 12.

Unfortunately, with respect to the embodiment shown in FIGS. 1A and 1B, there is typically a relatively large mismatch between the CTE of the adhesive material 25 and the molding material 28, respectively, with respect to the thinned silicon device wafer 12. As the final thickness 12T of the device wafer 12 has been reduced to thicknesses on the order of about 20-100 μm, the stresses induced by such a CTE mismatch can cause problems such as delamination and cracking of the thinned device wafer 12, bowing or warping of the device wafer 12, very high stress levels in localized regions of the device wafer 12, etc.

The present disclosure is directed to various methods of packaging stacked semiconductor devices using a glass window wafer with an engineered coefficient of thermal expansion (CTE) and packaged semiconductor devices using such a window wafer that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to stacked semiconductor devices using a glass window wafer with an engineered coefficient of thermal expansion (CTE) and methods of making such packaged semiconductor devices. One illustrative device disclosed herein includes a device substrate having a plurality of first die formed adjacent a front side of the device substrate, a glass window wafer attached to a back side of the device substrate, wherein the glass window wafer has a plurality of openings formed therein and a coefficient of thermal expansion that is within plus or minus 200-500% of the coefficient of thermal expansion of the device wafer, and a plurality of second die, each of which is positioned in one of the openings in the glass window wafer and electrically coupled to one of the first die.

Another illustrative device disclosed herein includes a device substrate comprised of silicon having a plurality of first die formed adjacent a front side of the device substrate, a glass window wafer attached to a back side of the device substrate, wherein the glass window wafer has a plurality of openings formed therein and a coefficient of thermal expansion that is within the range of 5.0-12.0 ppm/° C., and a plurality of second die, each of which is positioned in one of the openings in the glass window wafer and electrically coupled to one of the first die.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict various illustrative prior art stacked semiconductor devices;

FIG. 2 depicts one illustrative example of stacked semiconductor devices using a glass window wafer with an engineered coefficient of thermal expansion (CTE); and

FIG. 3A-3M depict various illustrative methods of making stacked semiconductor devices using a glass window wafer with an engineered coefficient of thermal expansion (CTE).

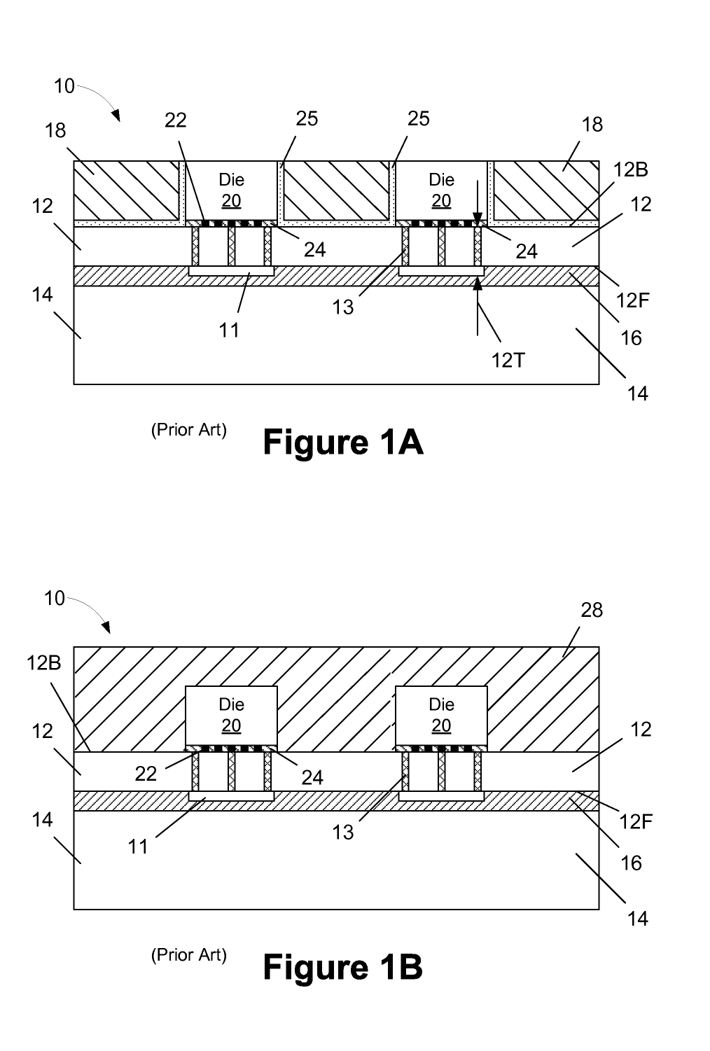

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to stacked semiconductor devices using a glass window wafer with an engineered coefficient of thermal expansion (CTE) and methods of making such packaged semiconductor devices. As will be readily apparent to those skilled in the art upon a complete reading of the present application, the methods disclosed herein may be employed with a variety of different technologies, e.g., NMOS, PMOS, CMOS, etc., and in packaging a variety of different devices, including, but not limited to, logic devices, memory devices, etc. With reference to the attached figures, various illustrative embodiments of the methods and devices disclosed herein will now be described in more detail.

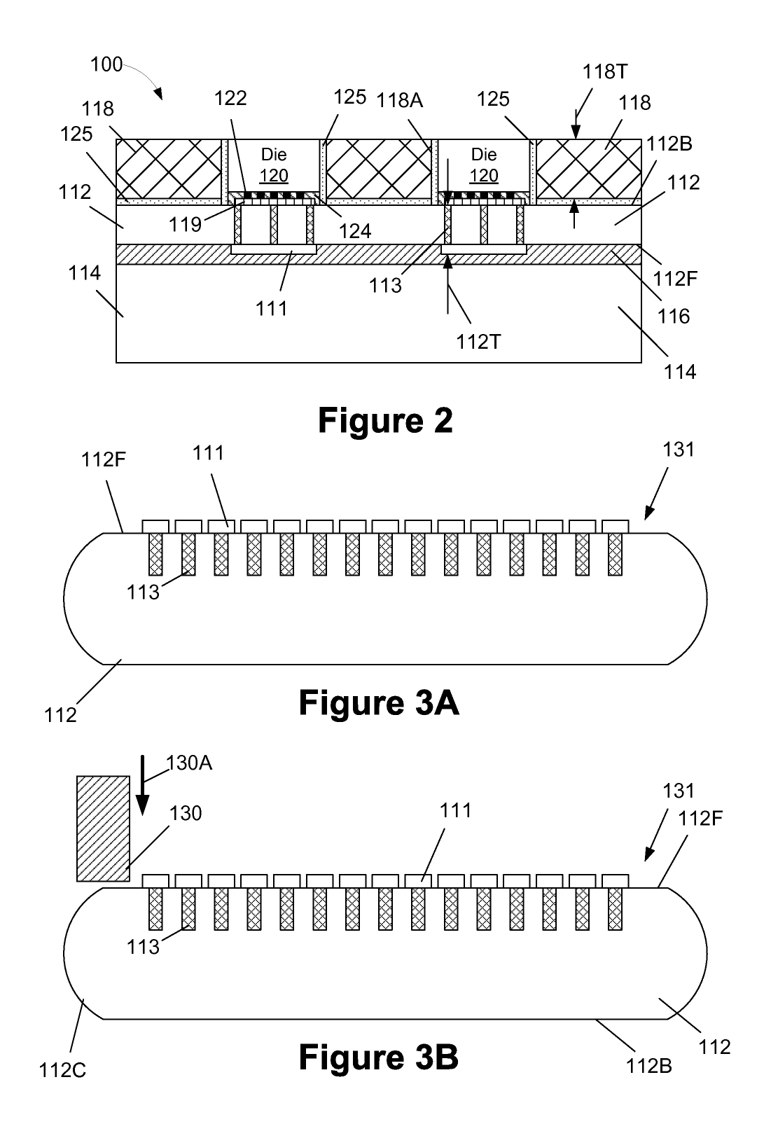

FIG. 2 depicts one illustrative example of a stacked semiconductor device 100 disclosed herein that includes a glass window wafer 118 or glass material with an engineered coefficient of thermal expansion (CTE) that is adjusted so as to reduce and/or eliminate CTE mismatch between the glass window wafer 118 and the final packaging of the device 100. FIG. 2 depicts the stacked semiconductor device 100 at a point during the packaging process after FEOL and BEOL processing activities have been performed to form a plurality of integrated circuit products or die 111 (only two of which are depicted) on a front side 112F of the device wafer or substrate 112. In the depicted example, the substrate 112 has been thinned to a final thickness 112T that may fall within the range of about 20-100 μm or less. The substrate 112 may have a variety of configurations, such as the depicted bulk silicon configuration. The substrate 112 may also have a silicon-on-insulator (SOI) configuration that includes a bulk silicon layer, a buried insulation layer and an active layer, wherein semiconductor devices are formed in and above the active layer. The substrate 112 may be made of silicon or it may be made of materials other than silicon. Thus, the terms “substrate” or “semiconducting substrate” should be understood to cover all semiconducting materials and all forms of such materials.

With continuing reference to FIG. 2, a plurality of illustrative TSVs 113 have also been formed in the device wafer 112 and they are conductively coupled to a plurality of conductive bond pads 119 that have been formed on the back side 112B of the device wafer 112. Moreover, it should be noted that, in this example, there are no conductive bumps formed on the front side 112F of the device wafer 112. The device wafer 112 is secured to a carrier wafer or substrate 114 by an adhesive material 116. Also depicted in FIG. 2 is the novel glass window wafer 118 and a plurality of stacked die 120 that are conductively coupled to the die 111 on the device wafer 112 by illustrative conductive bumps 122 and the TSVs 113. The stacked die 120 is positioned in openings 118A defined by the glass material of the glass window wafer 118. An under-fill material 124 fills the gaps between the stacked die 120, the device wafer 112 and the conductive bumps 122. Adhesive material 125 is used to secure the window wafer 118 to the device wafer 112 and the die 120 in the openings in the glass window wafer 118. The stacked die 120 and the die 111 depicted in the drawings are intended to be representative of any type or kind of integrated circuit product, e.g., a memory device, a logic device, an ASIC, etc. If desired, additional stacked die (not shown) may be positioned above the stacked die 120 shown in FIG. 2. One technique for stacking additional die above the die 120 would be to increase the thickness of the glass window wafer 118 so as to accommodate the additional die.

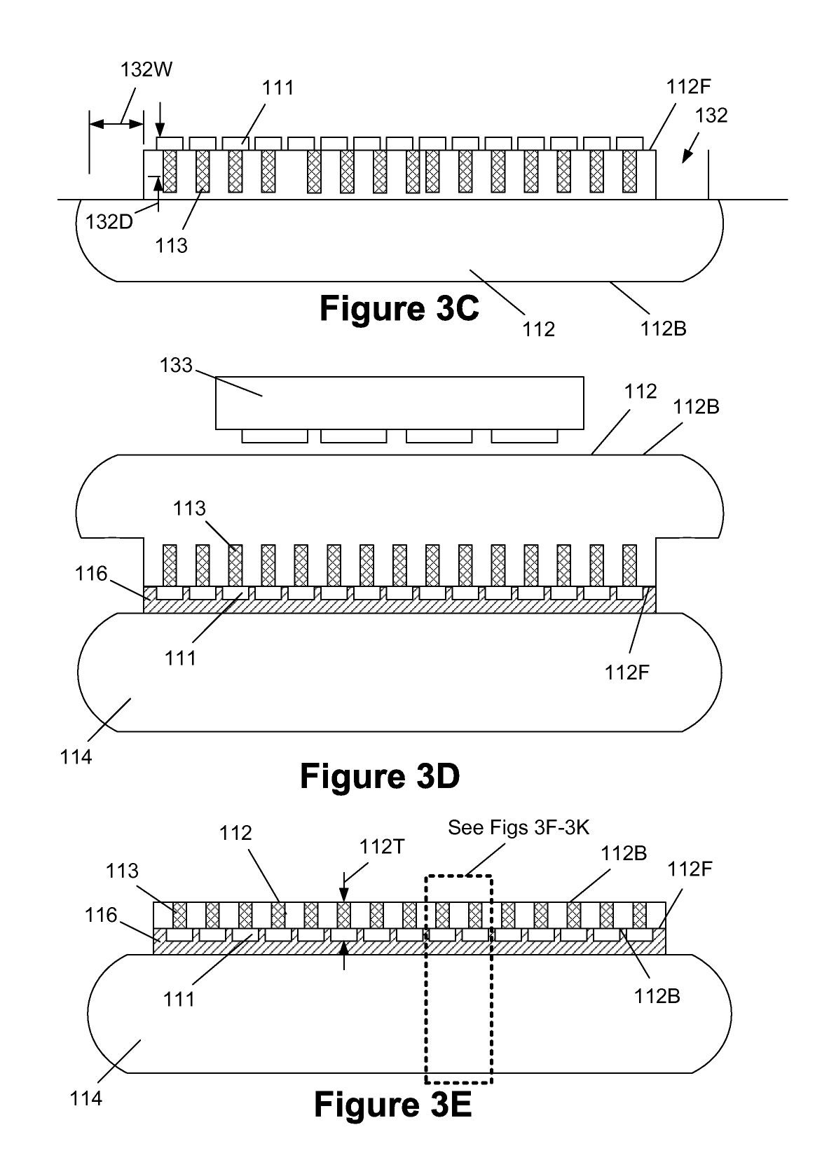

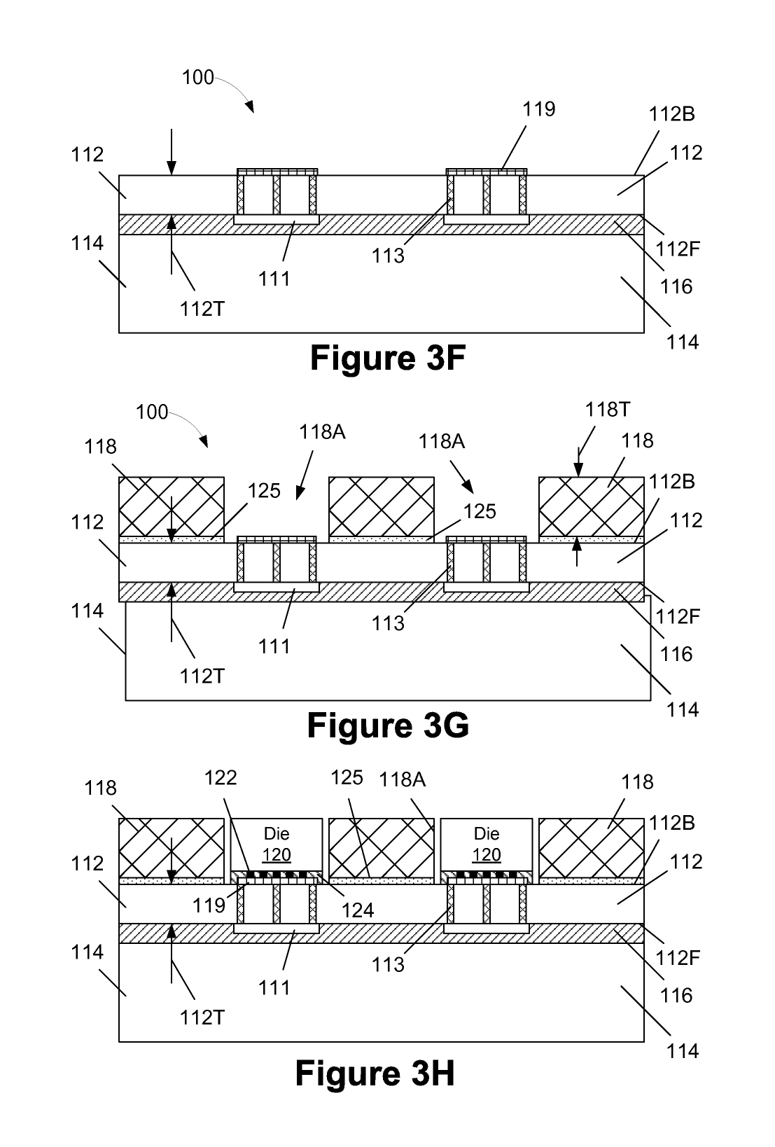

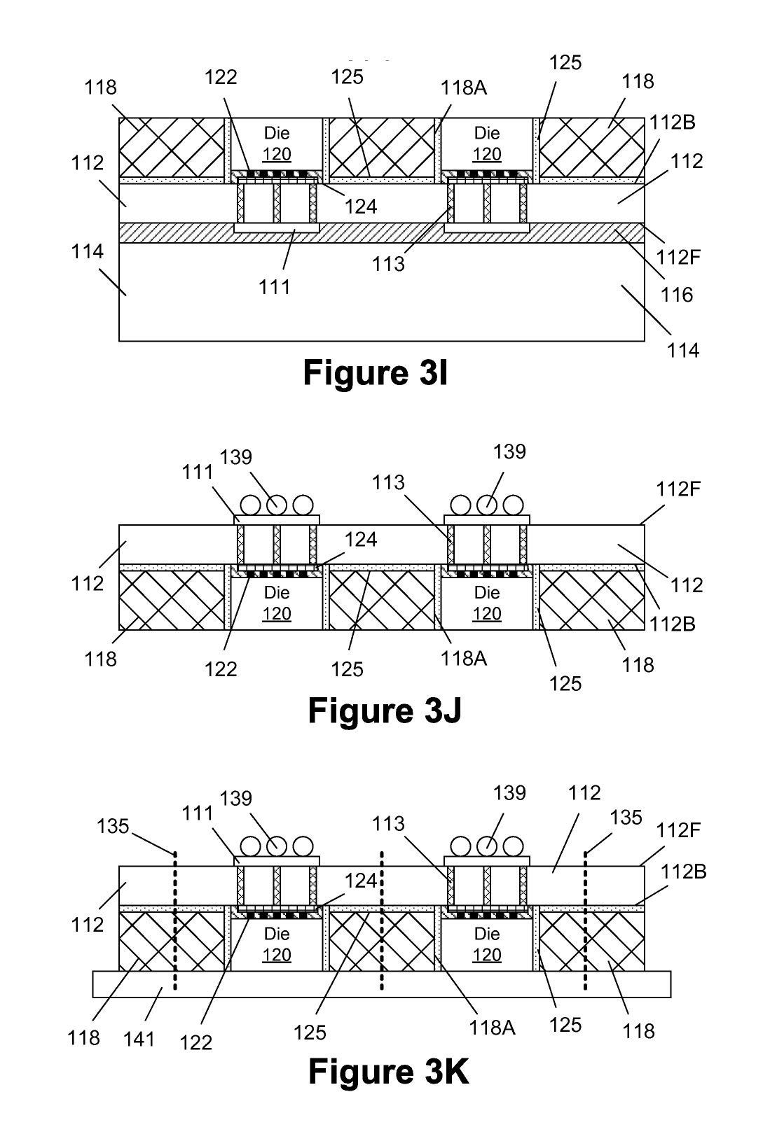

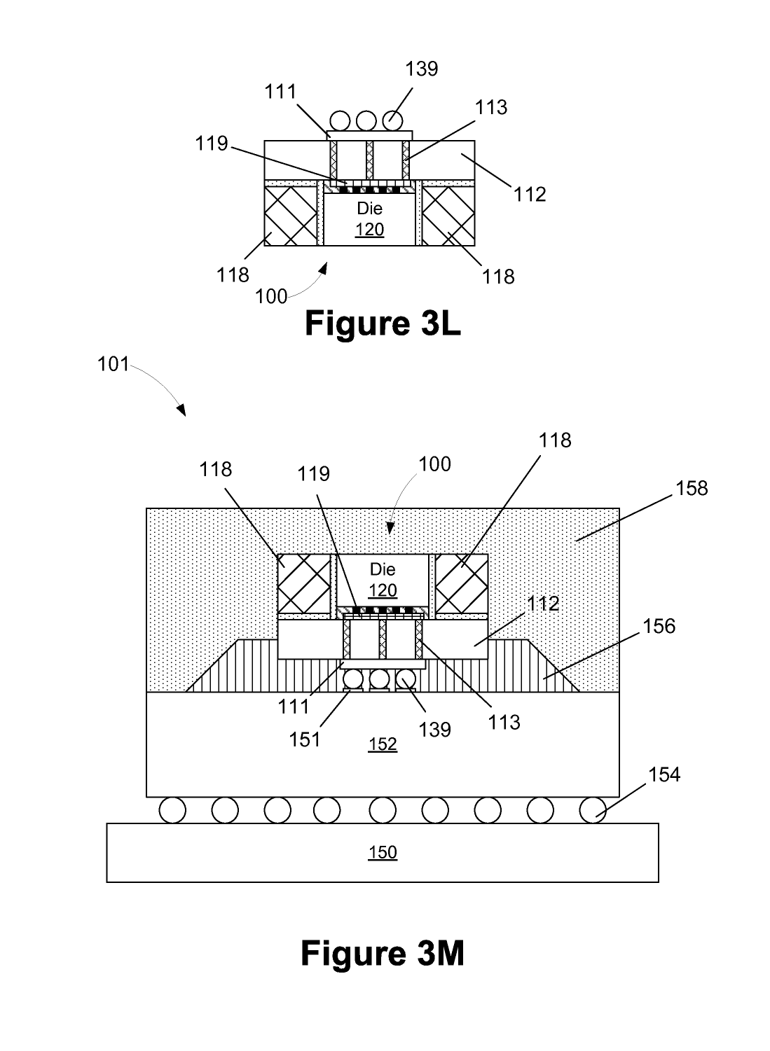

The glass window wafer 118 may be comprised of a silica-containing or sodium-containing glass material such as, for example, boron silicate glass, pyrex glass, quartz, etc. The thickness 118T of the glass window wafer 118 may vary depending upon the particular application, e.g., the thickness and number of stacked die 120, etc. In one example where only a single die 120 is attached to the device wafer 112, the thickness 118T may fall within the range of about 50-350 μm. The number, size and configuration of the openings 118A that are formed in the glass window wafer 118 may vary depending upon the particular application. The glass window wafer 118 may be supplied from a vendor in either a pre-patterned form, with the openings 118A already formed therein, or it may be supplied in an unpatterned form, in which case the semiconductor manufacturer could pattern the glass window wafer 118 using traditional photolithography tools and etch techniques or by laser drilling, etc. Importantly, the CTE of the glass window wafer 118 is specifically engineered so as to reduce any CTE mismatch between the glass window wafer 118 and the device wafer 112 and minimize or eliminate CTE mismatch between the device 100 and the packaging substrate and the PCB board, as discussed more fully below in connection with FIG. 3M.

The CTE of the glass material of the glass window wafer 118 may be adjusted or engineered by changing the composition of the glass material or by adding dopant materials to the glass during its manufacture. The techniques by which the CTE of glass material may be adjusted are well known to those skilled in the art of glass manufacturing. Thus, in one example, a semiconductor manufacturer may specify the desired CTE value (or range of values) for the glass window wafer 118 to the glass manufacturer that is appropriate for the stacked semiconductor device 100 under consideration. The CTE of the various materials can be measured using interferometry which looks at the changes in the interference pattern of monochromatic light, usually from a laser.

FIG. 3A-3M depict one illustrative example of making the stacked semiconductor device 100 disclosed herein having a glass window wafer 118 with an engineered CTE, as described above. FIG. 3A depicts the device wafer 112 after all FEOL and BEOL activities have been performed, wherein a plurality of the illustrative integrated circuit products or die 111 have been formed on the front side 112F of the device substrate 112. Typically, the device substrate 112 may have a starting thickness, as received from the wafer supplier, of about 775 μm. Ultimately, depending upon the particular application, prior to performing dicing operations to separate the plurality of die 111, the device substrate 112 will be thinned to a final thickness that may fall within the range of about 20-100 μm. Typically, the die 111 are not formed on the very outer edge region 131 of the device substrate 112.

In this example, as shown in FIG. 3B, the thinning process begins by using a dicing saw (not shown) and a schematically depicted dicing saw blade 130 to remove portions of the device substrate 112 near the edge region 131. As depicted, the device substrate 112 has curved outer edges 112C. In general, the spinning saw blade 130 is moved downward, as indicated by the arrow 130A, as the device substrate 112 is rotated on a wafer stage (not shown). As shown in FIG. 3C, this phase of the thinning process results in the formation of recesses 132 adjacent the edge region 131 on the front side 112F of the device substrate 112. The depth 132D and width 132W of the recesses 132 may vary depending upon the application and the final desired thickness of the device substrate 112. Typically, the depth of the recesses 132 is slightly greater than the desired final thickness of the device substrate 112. In one example, the depth 132D may fall within the range of about 100-400 μm and the width 132W may fall within the range of about 200-700 μm. In effect, the recesses 132 are formed to remove the curved outer edges 112C adjacent the front side 112F of the device substrate 112 for a depth that is greater than the final desired thickness of the device substrate 112.

Next, in this example, as shown in FIG. 3D, the front side 112F of the device wafer 112 is attached to the carrier wafer 114 using the adhesive material 116. Then, a schematically depicted grinding wheel 133 is used to grind the back side 112B of the device substrate 112 to reduce the overall thickness of the device substrate 112. FIG. 3E depicts the device wafer 112 after the grinding process has been completed, i.e., after the device substrate 112 has been thinned to its final desired thickness 112T.

As indicated in FIG. 3E, FIGS. 3F-3K depict only a portion of the device wafer 112/carrier wafer 114 assembly. In the example depicted in FIGS. 3F-3K, the conductive bumps 122 are formed on the stacked die 120 (see FIG. 2). Thus, as shown in FIG. 3F, there are no conductive bumps shown on the back side 112B of the device wafer 112 at this point in the process flow. However, after the device wafer 112 was thinned, the illustrative conductive bond pads 119 are formed on the back side 112B of the device wafer 112. If the stacked die combination 100 involved formation of conductive bumps on the back side 112B of the substrate 112, such conductive bumps would be formed on the back side 112B of the substrate 112 prior to attaching the glass window wafer 118 to the device wafer. In FIG. 3G, the glass window wafer 118 has been secured to the back side 112B of the device wafer 112 by the adhesive material 125. In this illustrative example, the glass window wafer 118 was supplied from a vendor in a pre-patterned condition, i.e., with the illustrative openings 118A formed in the glass window wafer 118 when it was received from the vendor.

Next, as shown in FIG. 3H, the stacked die 120 are positioned in openings 118A formed in the glass window wafer 118. The stacked die 120 are electrically coupled to the die 111 (through the TSVs 113) on the device wafer 112 by the conductive bumps 122 that, in this example, are formed on the stacked die 120 before it is attached to the device wafer 112. A reflow heating process is then performed to establish electrical connection between the bumps 122 and the conductive bond pads 119 that are formed on the back side 112B of the device wafer 112. This heating process causes the conductive bumps (formed on either the die 120 or adjacent the back side 112B of the device wafer 112) to flow and bond with adjacent conductive structures, like the bonding pads 119. At this point, the under-fill material 124 is added to fill the gaps between the stacked die 120, the device wafer 112 and the conductive bumps 122. Then, as shown in FIG. 31, additional adhesive material 125 is used to secure the die 120 in the openings 118A in the glass window wafer 118.

Next, as shown in FIG. 3J, the assembly has been flipped and the support wafer 114 and adhesive material 116 have been removed. Thereafter, schematically depicted conductive bumps 139 are formed on the front side 112F of the device wafer 112.

Next, as shown in FIG. 3K, a dicing tape 141 is mounted on the back side 112B of the device wafer 112. Thereafter, dicing operations may be performed from the front side 112F of the device wafer 112 to physically separate or “singulate” the illustrative die 111 along illustrative cut lines 135 that correspond to scribe lines on the device wafer 112. An illustrative stacked die combination 100 is depicted in FIG. 3L after dicing operations have been performed.

FIG. 3M depicts the stacked die combination 100 after additional packaging operations have been performed. More specifically, the assembled die package 100 is comprised of a printed circuit board (PCB) or printed wire board (PWD) 150, a package substrate 152, the stacked die combination 100, under-fill material 156 and molding material 158. A plurality of illustrative conductive bumps 154 establishes electrical connection between the board 150 and the packaging substrate 152. The conductive bumps 139 on the stacked die combination 100 are conductively coupled to the package substrate 152. The package substrate 152 may be made of silicon, ceramics or organic material. Importantly, using the novel techniques and structures disclosed herein, the CTE of the glass window wafer 118 is specifically engineered so as to effectively increase the CTE of the combined stacked die combination depicted in FIG. 3L. Increasing the effective CTE of the overall stacked die combination 100 will tend to minimize or eliminate CTE mismatch between the stacked die combination device 100 and the packaging substrate 152. By way of example only, the molding material 158 may have a CTE of about 10 ppm/° C., the under-fill material 154 may have a CTE of about 30 ppm/° C., the package substrate 152 may have a CTE of about 12 ppm/° C. and the PCB board 150 may have a CTE of about 18 ppm/° C. In one illustrative example, the CTE of the glass window wafer 118 may be engineered such that it is within the plus or minus 200-500% of the CTE of the material of the device substrate 112. In one particular example, the CTE of the glass window wafer 118 may be engineered such that the CTE of the glass window wafer 118 is closer to that of silicon (CTE=2.6 ppm/° C.), e.g., a CTE falling within the range of about 5-6 ppm/° C. In some cases, the CTE of the glass window wafer 118 may be engineered such that the CTE of the glass window wafer 118 is closer to the CTE of the package substrate 152 and the board 150, e.g., the CTE of the glass window wafer 118 may fall within the range of about 10-12 ppm/° C.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a device semiconducting substrate having a plurality of first die formed adjacent a front side of said device substrate, said device substrate having a substrate coefficient of thermal expansion;
a glass window wafer attached to a back side of said device substrate, said glass window wafer having a plurality of openings formed therein and a coefficient of thermal expansion that is within plus or minus 200-500% of the substrate coefficient of thermal expansion; and
a plurality of second die, each of which is positioned in one of said openings in said glass window wafer and electrically coupled to one of said first die.

2. The device of claim 1, wherein said device substrate is comprised of silicon and wherein said coefficient of thermal expansion of said glass window wafer is within the range of 5-12 ppm/° C.

3. The device of claim 1, wherein said first die comprises one of a logic device, a memory device and an application specific integrated circuit device, and wherein said second die comprises one of a logic device, a memory device and an application specific integrated circuit device.

4. The device of claim 1, further comprising a plurality of conductive bumps formed on each of said second die.

5. The device of claim 4, further comprising a plurality of conductive bond pads formed on a back side of said device substrate, each of which is adapted to be conductively couple to said conductive bumps on one of said second die.

6. The device of claim 1, further comprising a plurality of conductive through-substrate vias formed in said device substrate.

7. A device, comprising:
a device substrate comprised of silicon and having a plurality of first die formed adjacent a front side of said device substrate;
a glass window wafer attached to a back side of said device substrate, said glass window wafer having a plurality of openings formed therein and a coefficient of thermal expansion that is within the range of 5-12 ppm/° C.; and
a plurality of second die, each of which is positioned in one of said openings in said glass window wafer and electrically coupled to one of said first die.

8. The device of claim 7, further comprising a plurality of conductive through-substrate vias formed in said device substrate.

9. A device, comprising:
a semiconducting substrate having a first die formed adjacent a front side of said substrate, said substrate having a substrate coefficient of thermal expansion;
a glass material attached to a back side of said substrate, said glass material defining an opening, said glass material having a coefficient of thermal expansion that is within plus or minus 200-500% of the substrate coefficient of thermal expansion; and
a second die positioned in said opening defined by said glass material, said second die being electrically coupled to said first die.

10. The device of claim 9, further comprising a plurality of conductive through-substrate vias formed in said device substrate.

11. A device, comprising:
a semiconducting silicon substrate having a first die formed adjacent a front side of said substrate, said substrate having a substrate coefficient of thermal expansion;
a glass material attached to a back side of said substrate, said glass material defining an opening, said glass material having a coefficient of thermal expansion that is within the range of 5-12 ppm/° C.; and
a second die positioned in said opening defined by said glass material, said second die being electrically coupled to said first die.

12. The device of claim 11, further comprising a plurality of conductive through-substrate vias formed in said device substrate.

13. A method, comprising:
attaching a glass window wafer to a back side of a device semiconducting substrate having a plurality of first die formed adjacent a front side of said device substrate, said glass window wafer having a plurality of openings formed therein and a coefficient of thermal expansion that is within plus or minus 200-500% of the a coefficient of thermal expansion of said device substrate;
positioning a second die in each of said openings; and
electrically coupling each of said second die to one of said first die.

14. The method of claim 13, wherein attaching said glass window wafer to said back side of said device semiconducting substrate comprises gluing said glass window wafer to said back side of said device semiconducting substrate.

15. The method of claim 13, wherein electrically coupling said second die to said first die comprises performing a heating process to reflow conductive bumps positioned between said second die and said device substrate.

16. A method, comprising:
attaching a glass window wafer to a back side of a device semiconducting silicon substrate having a plurality of first die formed adjacent a front side of said device substrate, said glass window wafer having a plurality of openings formed therein and a coefficient of thermal expansion that is within the range of 5-12 ppm/° C.;
positioning a second die in each of said openings; and
electrically coupling each of said second die to one of said first die.

17. The method of claim 16, wherein attaching said glass window wafer to said back side of said device semiconducting substrate comprises gluing said glass window wafer to said back side of said device semiconducting substrate.

18. The method of claim 16, wherein electrically coupling said second die to said first die comprises performing a heating process to reflow conductive bumps positioned between said second die and said device substrate.
